(19) United States
(12) Patent Application Publication
(10) Pub. No.: US 2015/0043172 A1
(43) Pub. Date: Feb. 12, 2015

(54) CIRCUIT MODULE AND METHOD OF PRODUCING CIRCUIT MODULE

(71) Applicant: Taiyo Yuden Co., Ltd., Tokyo (JP)

(72) Inventors: Eiji MUGIYA, Tokyo (JP); Kenzo KITAZAKI, Tokyo (JP); Masaya SHIMAMURA, Tokyo (JP); Tetsuo SAJI, Tokyo (JP); Hiroshi NAKAMURA, Tokyo (JP)

(73) Assignee: Taiyo Yuden Co., Ltd., Tokyo (JP)

(21) Appl. No.: 14/103,601

(22) Filed: Dec. 11, 2013

(30) Foreign Application Priority Data
Aug. 9, 2013 (JP) 2013-167114

(51) Int. Cl. H05K 1/02; H05K 3/30

(52) U.S. Cl. CPC H05K 1/0218; H05K 3/303
USPC 361/728; 29/832

(57) ABSTRACT

There is provided a circuit module and a method of producing the same where interlayer wirings of a circuit substrate are prevented from damaging by laser irradiation, and a shield is assuredly electrically connected to the superficial conductor of the circuit substrate. The circuit substrate includes mount components, a sealing body, and a shield. The circuit substrate is a multi-layer substrate on which interlayer wirings are formed, and includes a mount surface on which a superficial conductor is disposed. The mount components are mounted on the mount surface. The sealing body is formed on the mount surface, covers the mount component and has a trench including a first trench section reaching the superficial conductor and a second trench section not reaching the superficial conductor. The shield has an outer shield section and an inner shield section.

### CROSS-REFERENCE TO A RELATED APPLICATION

This application claims priority under 35 U.S.C. §119 to Japanese Patent Application No. JP 2013-167114 filed on Aug. 9, 2013, the entire content of which is hereby incorporated herein by reference in its entirety

### FIELD

The present disclosure relates to a circuit module including a circuit substrate on which at least one mount component is mounted and sealed.

### BACKGROUND

A widely-used circuit module includes a circuit substrate on which at least one mount component is mounted and a peripheral of the mount component is sealed by a sealing body made of a synthetic resin etc. When the mount component is a radiocommuication element, a surface of the sealing body is coated with a conductive material to be used as a shield against interruption induced by electromagnetic waves (hereinafter referred to as electromagnetic interruption). The electromagnetic interruption is interference, unnecessary radiation or the like, for example. By providing the shield, the electromagnetic interruption caused by the electromagnetic waves emitted from the mount component in the shield against electronic devices etc. outside of the shield is prevented (emission is improved), or the electromagnetic interruption caused by the electromagnetic waves emitted outside from the shield against the mount component in the shield is prevented (immunity is improved).

In addition, when a plurality of mount components are mounted on the circuit substrate, there is developed a circuit module where the shields are provided to separate the mount components in order to prevent the electromagnetic interruption between the mount components. As the mount components are covered with the sealing bodies as described above, the sealing bodies are partly removed to form trenches (grooves) and the trenches are filled with a conductive material to provide the shields between the mount components.

For example, Japanese Patent Application Laid-open No. 2004-95607 discloses a module component where split grooves are formed on a sealing body covering mount components, and a metal film is formed within the split grooves. The metal film is connected to a ground pattern formed on a circuit substrate and functions as a shield.

A sealing layer can be removed by irradiating the sealing body with laser. For example, Japanese Patent Application Laid-open No. 2010-56180 discloses a circuit module where penetrating holes are formed in a sealing layer by irradiating the sealing layer with laser. The penetrating holes are filled with a conductive material to form through hole electrodes.

### SUMMARY

When the trenches are formed by laser irradiation, the sealing body is irradiated and scanned with laser and the sealing body is removed linearly, whereby the trench is formed. However, the laser irradiation may damage interlayer wirings of a multi-layer substrate positioned at a lower side of the sealing body, and may break the interlayer wirings.

Meanwhile, when laser irradiation energy (energy provided by the laser in a given area of the sealing body) is decreased in order to prevent the interlayer wirings from damaging, depths of the trenches may be insufficient. Some of the circuit modules include the shield electrically connected to a superficial conductor of the circuit substrate via the trenches. In this case, if the depths of the trenches are insufficient, the shield does not reach the superficial conductor and does not electrically connected to the superficial conductor.

In view of the above-described circumstances, it is desirable to provide a circuit module and a method of producing the same where interlayer wirings of a circuit substrate are prevented from damaging by laser irradiation, and a shield is assuredly electrically connected to the superficial conductor of the circuit substrate.

According to an embodiment of the present disclosure, there is provided a circuit module including a circuit substrate, at least one mount component, at least one sealing body, and a shield.

The circuit substrate is a multi-layer substrate on which interlayer wirings are formed, and includes a mount surface on which a superficial conductor is disposed.

The mount component is mounted on the mount surface.

The sealing body is formed on the mount surface, covers the mount component and has a trench including a first trench section reaching the superficial conductor and a second trench section not reaching the superficial conductor, which is formed from a main surface of the sealing body to the mount surface.

The shield has an outer shield section that covers the sealing body and an inner shield section formed within the trench.

In order to achieve the object, a method of producing an circuit module according to an embodiment of the present disclosure includes preparing a circuit substrate being a multi-layer substrate on which interlayer wirings are formed and including a mount surface on which a superficial conductor is disposed.

A mount component is mounted on the mount surface.

A sealing body is formed on the mount surface that covers the mount component.

On the sealing body, a trench including a first trench section reaching the superficial conductor and a second trench section not reaching the superficial conductor is formed from a main surface of the sealing body to the mount surface.

A shield having an outer shield section that covers the sealing body and an inner shield section formed within the trench is formed.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIG. 1 is a perspective view of a circuit module according to a first embodiment of the present disclosure;

FIG. 2 is a plan view of the circuit module;

FIG. 3 is a sectional view of the circuit module (along the A-A line shown in FIG. 2);

FIG. 4 is a plan view showing sealing bodies of the circuit module (along the B-B line shown in FIG. 2);

FIG. 5 is an enlarged sectional view of the circuit module;

FIG. 6 is a plan view of the sealing bodies of the circuit module;

FIG. 7 is a sectional view of the sealing bodies etc. of the circuit module (along the B-B line shown in FIG. 6);

FIG. 8 is a plan view of the sealing bodies of the circuit module;

FIGS. 9A and 9B each is a sectional view of the sealing bodies etc. of the circuit module (along the B-B line and the C-C line shown in FIG. 8);

FIG. 10 is a sectional view of the sealing bodies etc. of the circuit module (along the D-D line shown in FIG. 8);

FIG. 11 is a sectional view of the sealing bodies etc. of the circuit module (along the D-D line shown in FIG. 8);

FIG. 12 is a sectional view of the sealing bodies etc. of the circuit module (along the D-D line shown in FIG. 8);

FIGS. 13A and 13B each is a sectional view of the circuit module (along the B-B line and the C-C line shown in FIG. 2);

FIG. 14 is a sectional view of the circuit module (along the D-D line shown in FIG. 2);

FIGS. 15A to 15C each is a schematic view showing a method of producing the circuit module;

FIGS. 16A to 16C each is a schematic view showing a method of producing the circuit module;

FIG. 17 is a plan view of a sealing body of a circuit module according to an alternative embodiment of the first embodiment of the present disclosure;

FIG. 18 is a schematic view of a circuit module according to a second embodiment of the present disclosure;

FIG. 19 is a sectional view of a circuit substrate of the circuit module;

FIG. 20 is a plan view of the circuit substrate and the mount components of the circuit module;

FIG. 21 is a plan view of the sealing body of the circuit module;

FIG. 22 is a sectional view of the sealing bodies etc. of the circuit module (along the D-D line shown in FIG. 21);

FIG. 23 is a sectional view of the circuit module;

FIG. 24 is a plan view of a sealing body of a circuit module according to an alternative embodiment of the second embodiment of the present disclosure; and

FIG. 25 is a sectional view of the circuit module.

### DETAILED DESCRIPTION OF EMBODIMENTS

A circuit module according to an embodiment of the present disclosure includes a circuit substrate, a mount component, a sealing body, and a shield.

The circuit substrate is a multi-layer substrate on which interlayer wirings are formed, and includes a mount surface on which a superficial conductor is disposed.

The mount component is mounted on the mount surface.

The sealing body is formed on the mount surface, covers the mount component and has a trench including a first trench section reaching the superficial conductor and a second trench section not reaching the superficial conductor formed from a main surface of the sealing body to the mount surface.

The shield has an outer shield section that covers the sealing body and an inner shield section formed within the trench.

In such a configuration, the inner shield section of the shield abuts on the superficial conductor via the first trench section, and is thus electrically connected to the superficial conductor. On the other hand, the second trench section does not reach the superficial conductor. Accordingly, the inter layer wirings formed on the circuit substrate will not be damaged by laser irradiation for forming the second trench section. In other words, the interlayer wirings of the circuit substrate are prevented from damaging by the laser irradiation, and the shield is assuredly electrically connected to the superficial conductor of the circuit substrate.

The second trench section may be formed at an end of the trench, and the first trench section may be formed between the second trenches.

In such a configuration, the second trench section can be a start point and a stop point of the laser irradiation for forming the trench. The laser energy is likely to concentrate when the irradiation is started and the irradiation is stopped. The formation of the second trench section at the start point and the stop point of the laser irradiation prevents the interlayer wirings from damaging by the laser irradiation. Meanwhile, the shield is assuredly electrically connected to the superficial conductor by the first trench section.

The interlayer wirings include a ground wiring electrically connected to a ground of the circuit module, and a non-ground wiring not electrically connected to the ground wiring.

The second trench section may be formed at the area where the non-ground wiring is disposed in a lower side of the sealing body, and the first trench section may be formed at the area where the non-ground wiring is not disposed in a lower side of the sealing body.

In such a configuration, the laser to form the trench does not reach the superficial conductor in the second trench section, whereby it is possible to prevent the non-ground wiring from damaging by the laser irradiation. The non-ground wiring is, for example, a signal line between mount components, which may require the damage prevention. Meanwhile, the first trench section assures the electrical connection between the shield and the superficial conductor.

The mount component may include a plurality of mount components.

The trench may be formed between the plurality of mount components such that the mount components are separated.

In such a configuration, the electromagnetic interruption between the mount components is shielded by the inner shield section, whereby it is possible to mount the mount components that can generate the electromagnetic interruption therebetween to one circuit module.

A method of producing an circuit module according to an embodiment of the present disclosure includes preparing a circuit substrate being a multi-layer substrate on which interlayer wirings are formed and including a mount surface on which a superficial conductor is disposed.

A mount component is mounted on the mount surface.

A sealing body is formed on the mount surface that covers the mount component.

On the sealing body, a trench including a first trench section reaching the superficial conductor and a second trench section not reaching the superficial conductor is formed from a main surface of the sealing body to the mount surface.

A shield having an outer shield section that covers the sealing body and an inner shield section formed within the trench is formed.

In such a production method, it is possible to produce a circuit module where the interlayer wirings of the circuit substrate are prevented from damaging by the laser irradiation, and the shield is assuredly electrically connected to the superficial conductor of the circuit substrate.

When the trench is formed, the second trench section is formed by starting the laser irradiation under first laser irradiation conditions, the first trench section is formed by scanning the laser under second laser irradiation conditions having irradiation energy higher than that of the first laser irradiation conditions, and the second trench section is formed by stopping the laser irradiation under the first laser irradiation conditions.

In such a production method, the laser irradiation energy (energy provided by the laser in a given area of the sealing body) is low (under the first laser irradiation conditions) at the start point and the stop point of the laser irradiation, the interlayer wirings of the circuit substrate is prevented from damaging by the laser irradiation. In addition, the laser irradiation energy is high (under the second laser irradiation conditions) during the laser scanning, the first trench section can reach the superficial conductor, i.e., the inner shield section can be electrically connected to the superficial conductor.

When the trench is formed, the second trench section may be formed by irradiating the area where the non-ground wiring is disposed in an upper side of the sealing body with laser under the first laser irradiation conditions, and the first trench section may be formed by irradiating the area where the non-ground wiring is not disposed in an upper side of the sealing body with laser under the second laser irradiation conditions having irradiation energy higher than that of the first laser irradiation conditions.

In such a configuration, the second trench section can be formed at the area where the non-ground wiring is disposed in an upper side of the sealing body, and the first trench section can be formed at the area where the non-ground wiring is not disposed in an upper side of the sealing body. As the second trench section does not reach the superficial conductor, the laser passes through the superficial conductor, whereby the non-ground wiring is prevented from damaging.

### First Embodiment

The circuit module according to a first embodiment of the present disclosure will be described.

### [Configuration of Circuit Module]

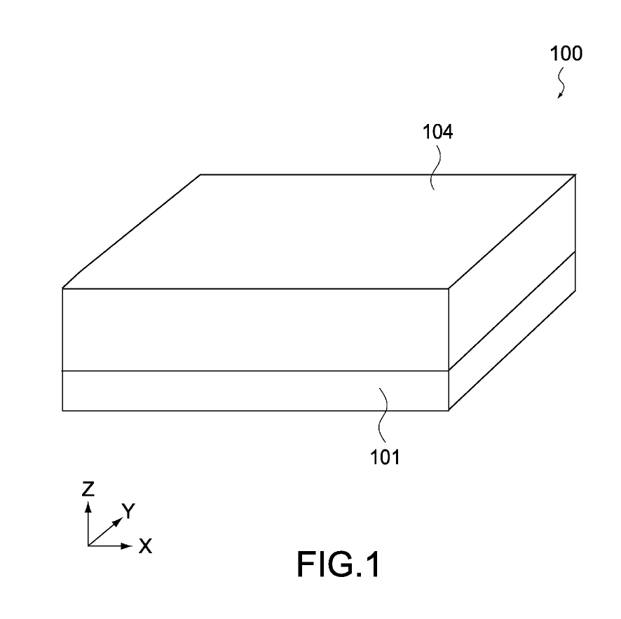

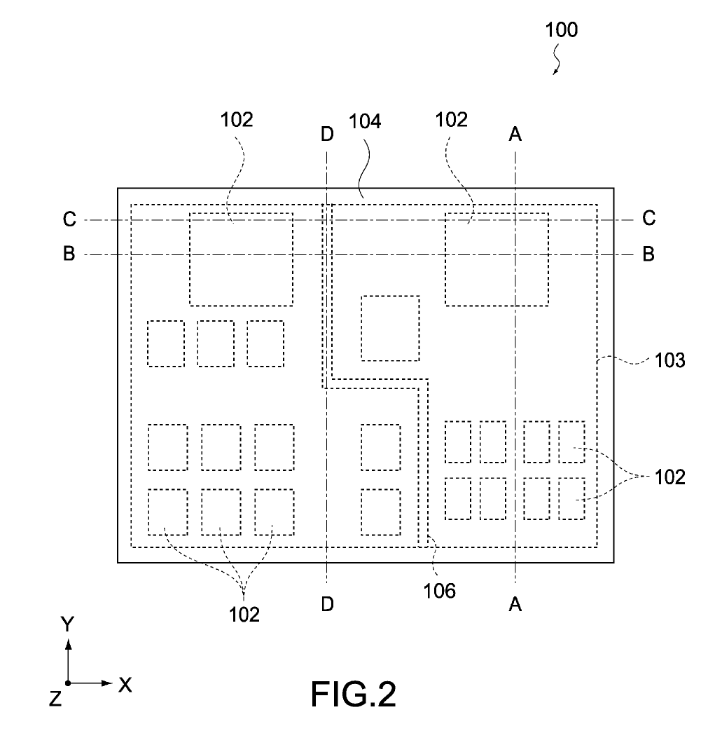

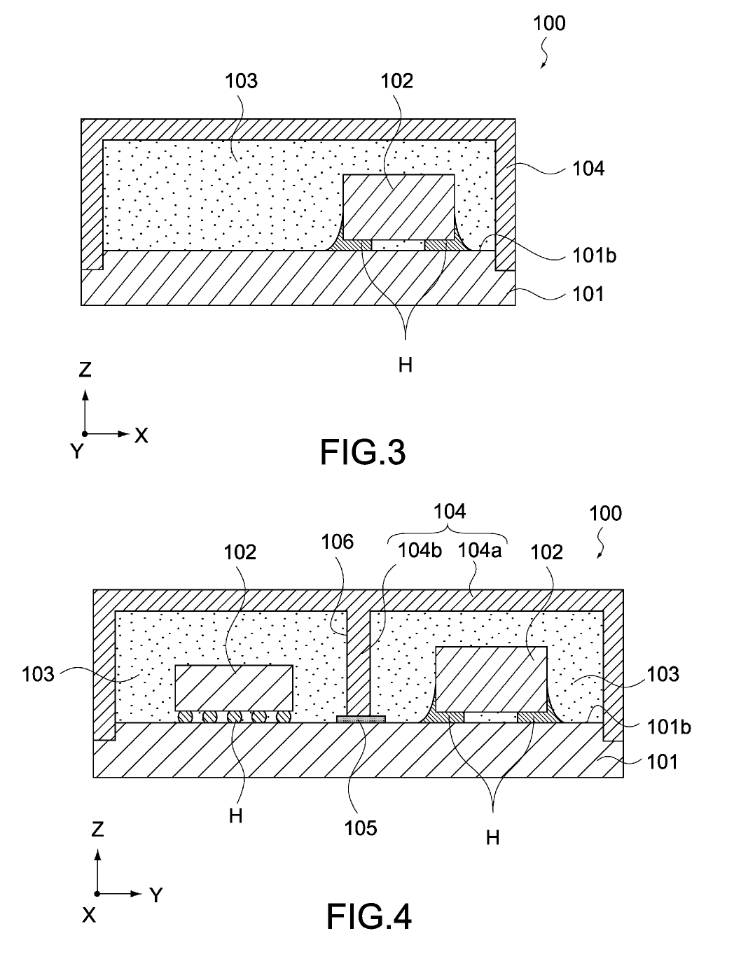

FIG. 1 is a perspective view of a circuit module 100 according to an embodiment of the present disclosure. FIG. 2 is a plan view of the circuit module 100. FIGS. 3 and 4 each is a sectional view of the circuit module 100. FIG. 3 is a sectional view of the circuit module 100 along the A-A line in FIG. 2. FIG. 4 is a sectional view of the circuit module 100 along the A-A line in FIG. 4. In each view, an X direction, a Y direction and a Z direction are orthogonal to each other.

As shown in FIGS. 1 to 4, the circuit module 100 includes a circuit substrate 101, mount components 102, sealing bodies 103, and a shield 104. Although a size or a shape of the circuit module 100 is not especially limited, the circuit module 100 may be a rectangular parallelepiped having a size of tens mm squares and a thickness of several mms.

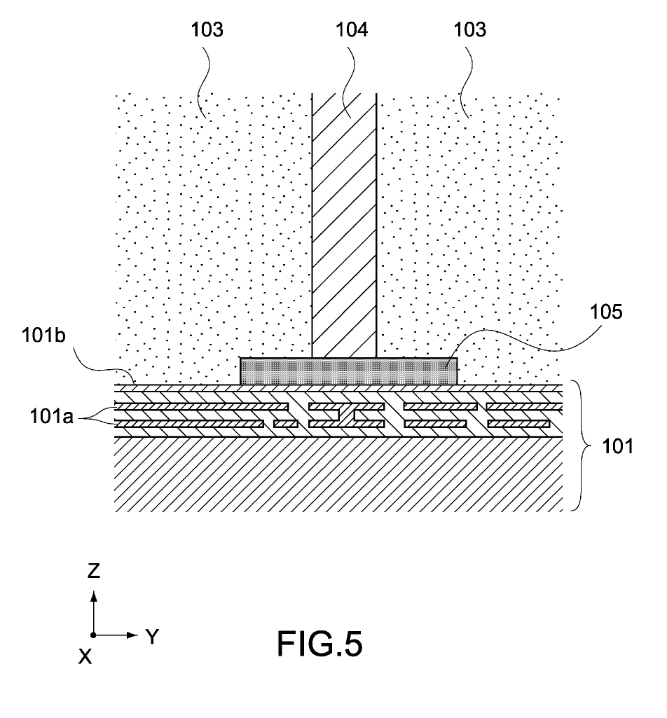

The mount components 102 etc. are mounted on the circuit substrate 101. FIG. 5 is a sectional view of the circuit substrate 101, and is an enlarged view of FIG. 4. As shown in FIG. 5, the circuit substrate 101 can be a multi-layer substrate on which a plurality of layers made of an insulating material such as a glass epoxy-based material and an insulating ceramic material are laminated. Within the layers, interlayer wirings 101a can be formed. The interlayer wirings 101a are not shown in other drawings. Hereinafter, a surface of the circuit substrate 101 on a side where the mount components 102 are mounted is defined as a mount surface 101b.

On the mount surface 101b, a superficial conductor 105 is disposed, as shown in FIGS. 4 and 5. The superficial conductor 105 is made of a conductive material, or may be a conductive paste applied and cured on the mount surface 101b or a metal film formed by plating etc. on the mount surface 101b. The superficial conductor 105 can be disposed on the mount surface 101b along a trench 106 as described later.

The superficial conductor 105 is connected to the interlayer wirings 101a formed within the circuit substrate 101, and can be electrically connected to the mount components 102 via the interlayer wirings 101a. Specifically, the superficial conductor 105 is electrically connected to a ground terminal of the circuit module 100, and therefore can have the same potential as a ground potential of the circuit module 100.

The mount component 102 mounted on the mount surface 101b of the circuit substrate 101 is an integrated circuit (IC), a capacitor, an inductor, a resistor, a crystal oscillator, a duplexer, a filter, a power amplifier, or the like, for example. The mount component 102 can be mounted on the mount surface 101b by solder joint using solder H. As shown in FIG. 2, the plurality of mount components 102 can be mounted on the circuit substrate 101. The number or placement of mount components 102 is not especially limited.

The sealing body 103 is made of a sealing material, and covers the mount components 102 on the mount surface 101b. For example, the sealing material is an insulating resin such as an epoxy resin to which silica or alumina is added. After the mount components 102 are mounted on the mount surface 101b, peripherals of the mount components 102 are filled with a fluid sealing material and the sealing material is cured to provide the sealing bodies 103.

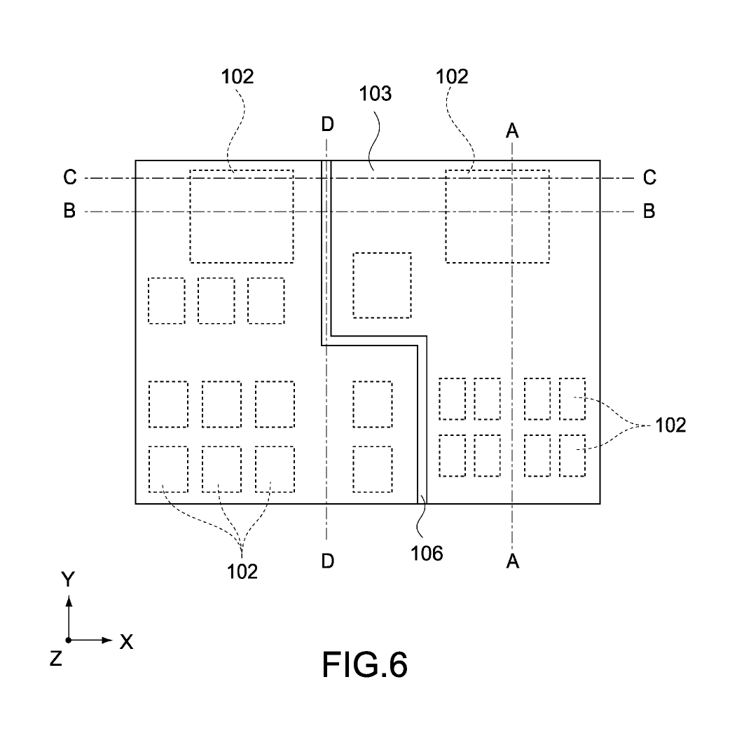

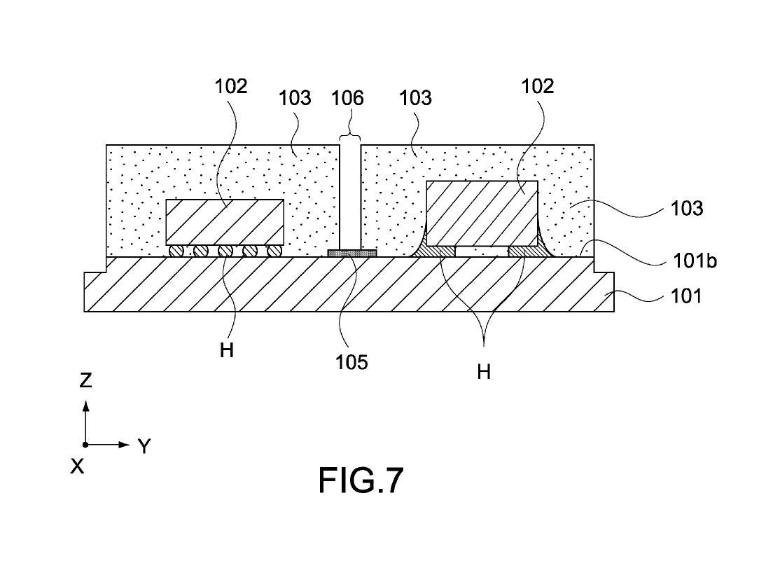

FIG. 6 is a plan view showing the sealing bodies 103 by omitting the shield 104 shown in FIG. 2. FIG. 7 is a sectional view showing the sealing bodies 103 by omitting the shield 104 shown in FIG. 4. As shown in FIGS. 6 and 7, the trench 106 is formed between the sealing bodies 103.

The trench 106 can be formed by removing the sealing bodies 103 in a groove shape. Details about the trench 106 and a method of forming the trench 106 are described later. As shown in FIG. 6, the trench 106 is formed between the plurality of mount components 102 such that the mount components 102 are separated. The trench 106 has a shape (a line shape) as shown in FIG. 6, but it is no limited thereto. The trench 106 may have a shape depending on types or positions of the mount components 102.

The shield 104 is made of a shielding material that is a conductive material, and functions as a shield against electromagnetic interruption. For example, the shielding material may be a conductive resin such as an epoxy resin containing conductive particles such as Ag and Cu, or may be a metal film formed on the sealing body 103 by plating etc.

The shield 104 has an outer shield section 104a covering the main surface of the sealing body 103 and an inner shield section 104b formed within the trench 106, as shown in FIG. 4. The inner shield section 104b abuts on the superficial conductor 105 via the trench 106 as shown in FIG. 4, and is electrically connected to the superficial conductor 105. Details about the inner shield section 104b will be described later.

The outer shield section 104a is successive with the inner shield section 104b, and is electrically connected to the superficial conductor 105 via the inner shield section 104b. As described above, the superficial conductor 105 can be a ground of the circuit module 100, and the shield 104 can have a ground potential.

The circuit module 100 has an overall configuration as described above. In the circuit module 100, the electromagnetic interruption can be prevented by the shield 104. Specifically, the electromagnetic interruption from outside of the circuit module 100 to the mount components 102, or the electromagnetic interruption from the mount components 102 to outside of the circuit module 100 is prevented by the outer shield section 104a. Also, the electromagnetic interruption between the mount components 102 is prevented by the inner shield section 104b.

### [About Trench and Inner Shield Section]

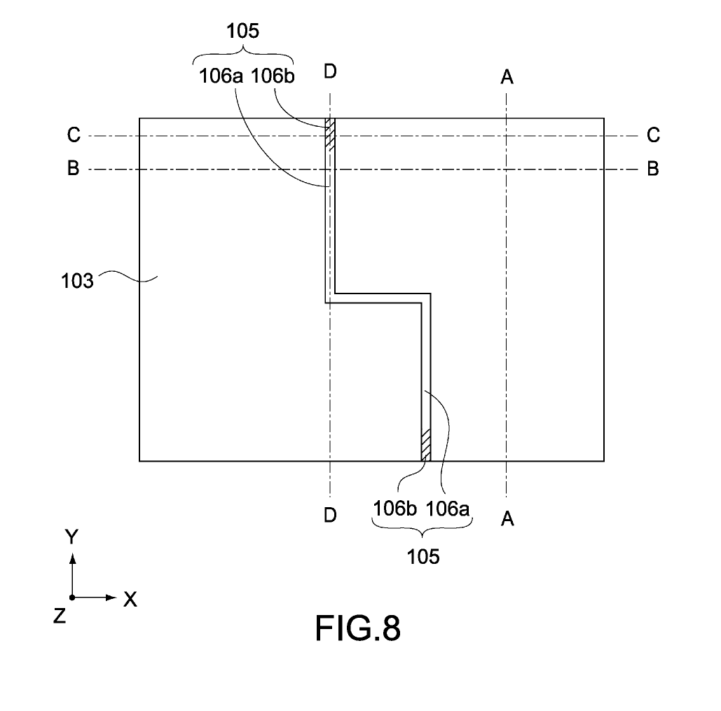

Trench 106 has different depths (in the Z direction). FIG. 8 is a plan view of the sealing body 103 showing the trench 106 and is a view omitting the mount components 102 from FIG. 6. As shown in FIG. 8, the trench 106 has a first trench section 106a and second trench sections 106b. The second trench sections 106b are shown by hatched lines in FIG. 8.

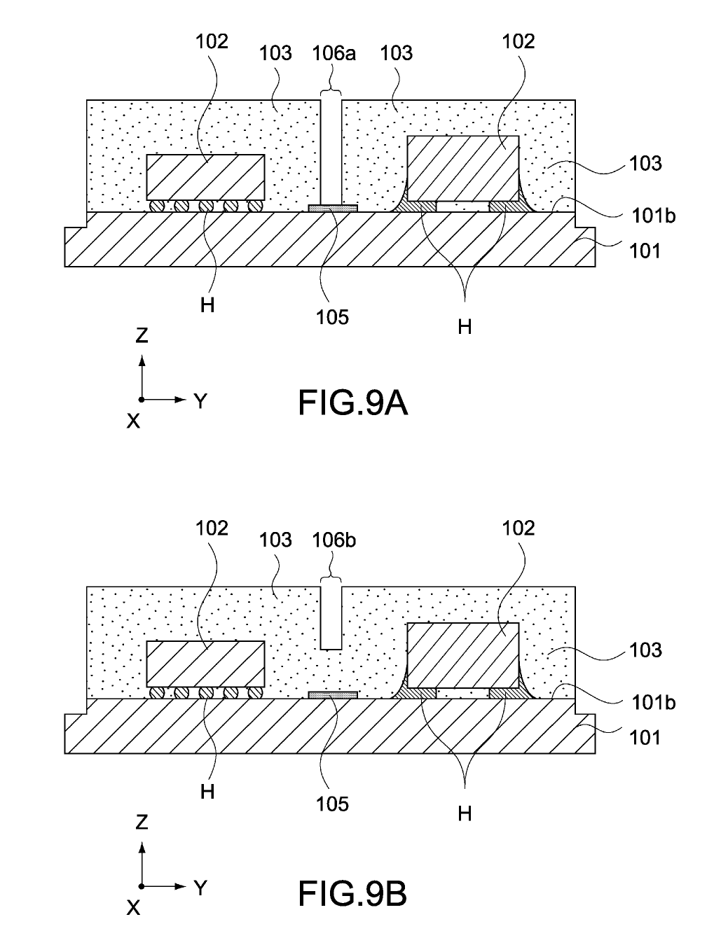

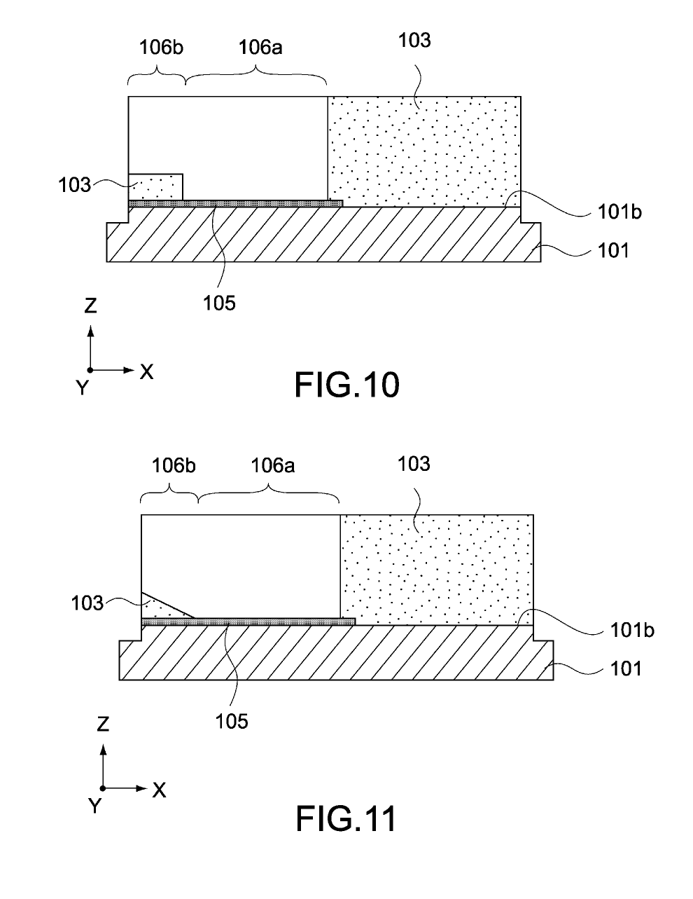

FIGS. 9A and 9B each is a sectional view of the sealing bodies 103 showing the trench 106. FIG. 9A shows the first trench section 106a. FIG. 9B shows the second trench section 106b. In addition, FIG. 9A is a sectional view along the B-B line shown in FIG. 8. FIG. 9B is a sectional view along the C-C line shown in FIG. 8. FIG. 10 is a sectional view of the sealing bodies 103 etc. showing the trench 106 seen from a different direction as illustrated in FIGS. 9A and 9B, and is a sectional view along the D-D line shown in FIG. 8.

The first trench section 106a occupies a most part of the trench 106 as shown in FIG. 8, and has a depth reaching the superficial conductor 105 as shown in FIGS. 9A and 10. On the other hand, the second trench section 106b is formed at an end or ends of the trench 106 as shown in FIG. 8, and does not reach the superficial conductor 105 as shown in FIGS. 9A and 10.

Although details are described later, the trench 106 can be formed by irradiating and scanning the sealing bodies 103 with laser. By adjusting the laser irradiation conditions on that occasion, the first trench section 106a and the second trench section 106b can be formed.

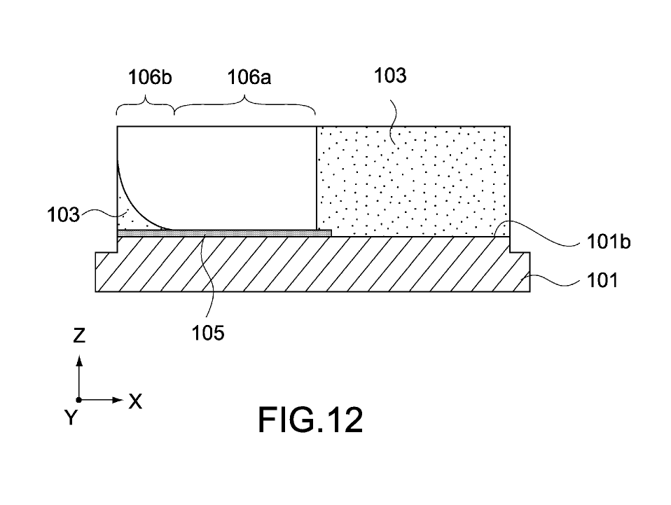

The second trench section 106b may have a depth so that the second trench section 106b does not reach the superficial conductor 105, and may have a non-uniform thickness. FIGS. 11 and 12 each is a sectional view of the sealing bodies 103 etc. showing the second trench section 106 having the non-uniform thickness. As shown in FIGS. 11 and 12, the second trench section 106b may be gradually deep as the second trench section 106b approaches to the first trench section 106a.

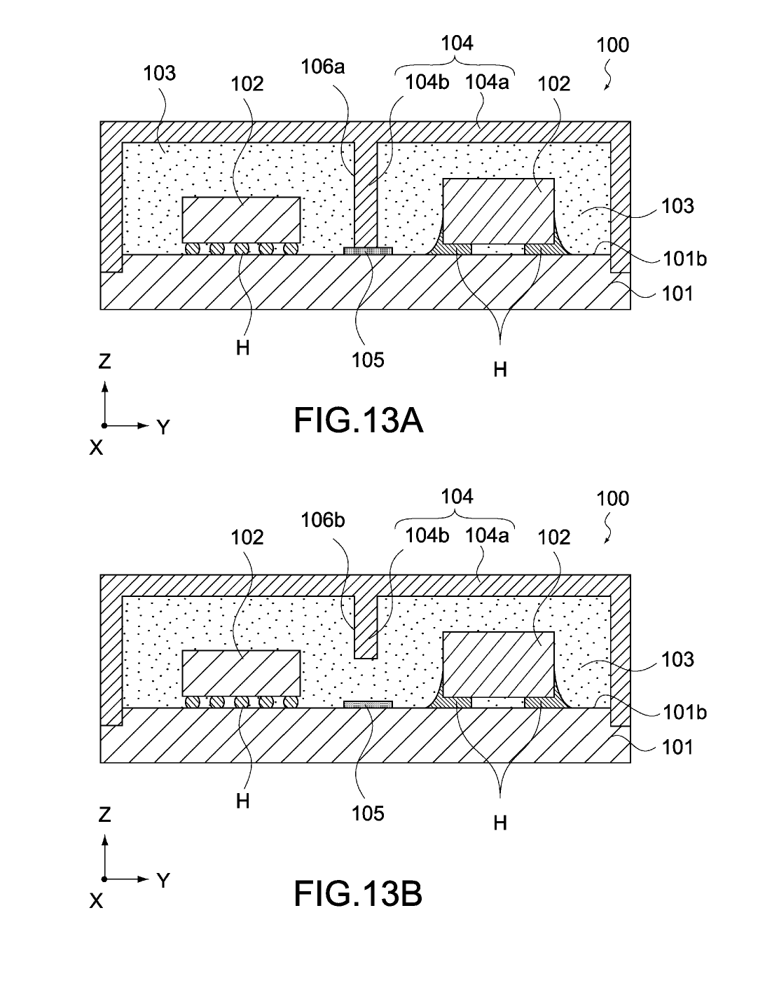

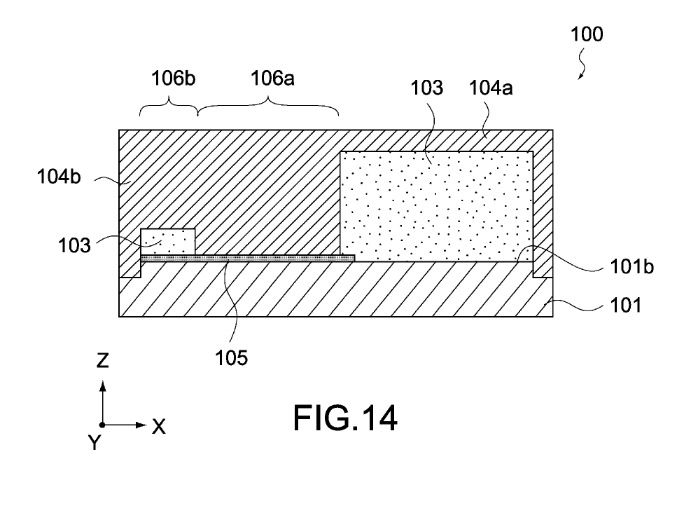

The inner shield section 104b is formed within the trench 106 as described above. FIGS. 13A and 13B each is a sectional view of the circuit module 100 showing the inner shield section 104b. FIG. 13A shows the inner shield section 104b formed within the first trench section 106a, and FIG. 13B shows the inner shield section 104b formed within the second trench section 106b. FIG. 13A is a sectional view along the B-B line shown in FIG. 2, and FIG. 13B is a sectional view along the C-C line shown in FIG. 2. FIG. 14 is a sectional view of the circuit module 100 showing the inner shield section 104b seen from a different direction as illustrated in FIG. 13, and a sectional view along the D-D line shown in FIG. 2.

As shown in FIGS. 13A and 14, the inner shield section 104b abuts on the superficial conductor 105 via the first trench section 106a, and is electrically connected to the superficial conductor 105. In other words, as shown in FIGS. 13B and 14, the inner shield section 104b is assuredly electrically connected to the superficial conductor 105, even though a portion of the inner shield section 104b (a portion formed within the second trench section 106b) does not abut directly on the superficial conductor 105.

The trench 106 and the inner shield section 104b have such a configuration. As described above, as the inner shield section 104b (i.e., the shield 104) is assuredly electrically connected to the superficial conductor 105, the shield 104 effectively functions as the shield.

### [Method of Producing Circuit Module]

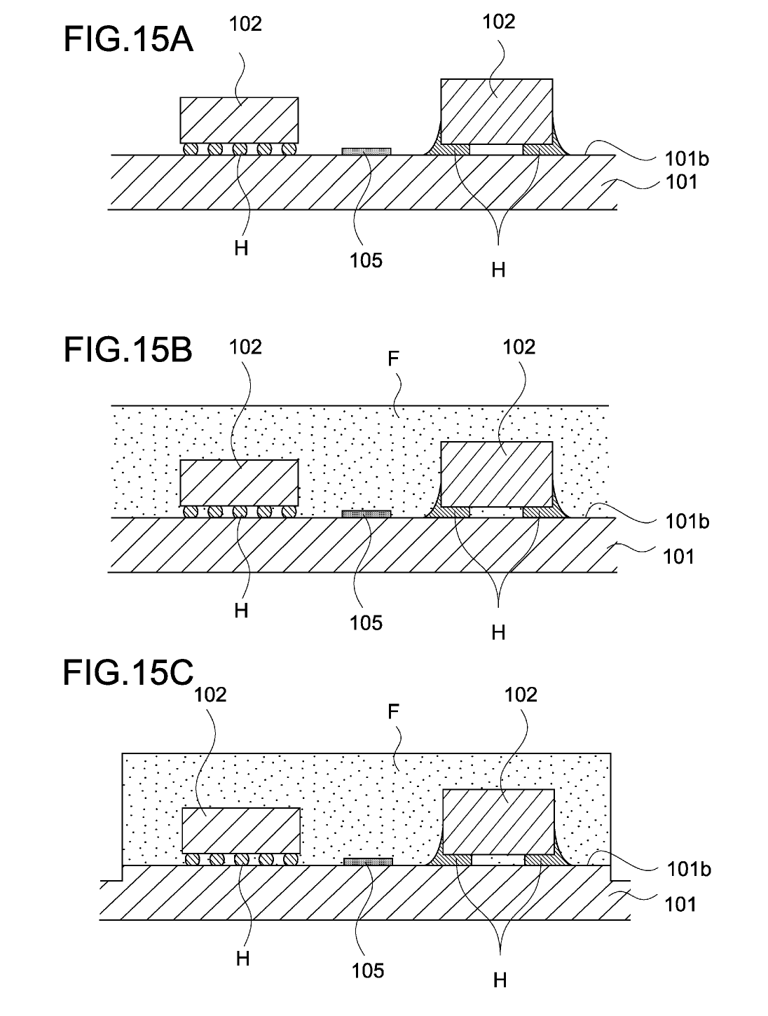

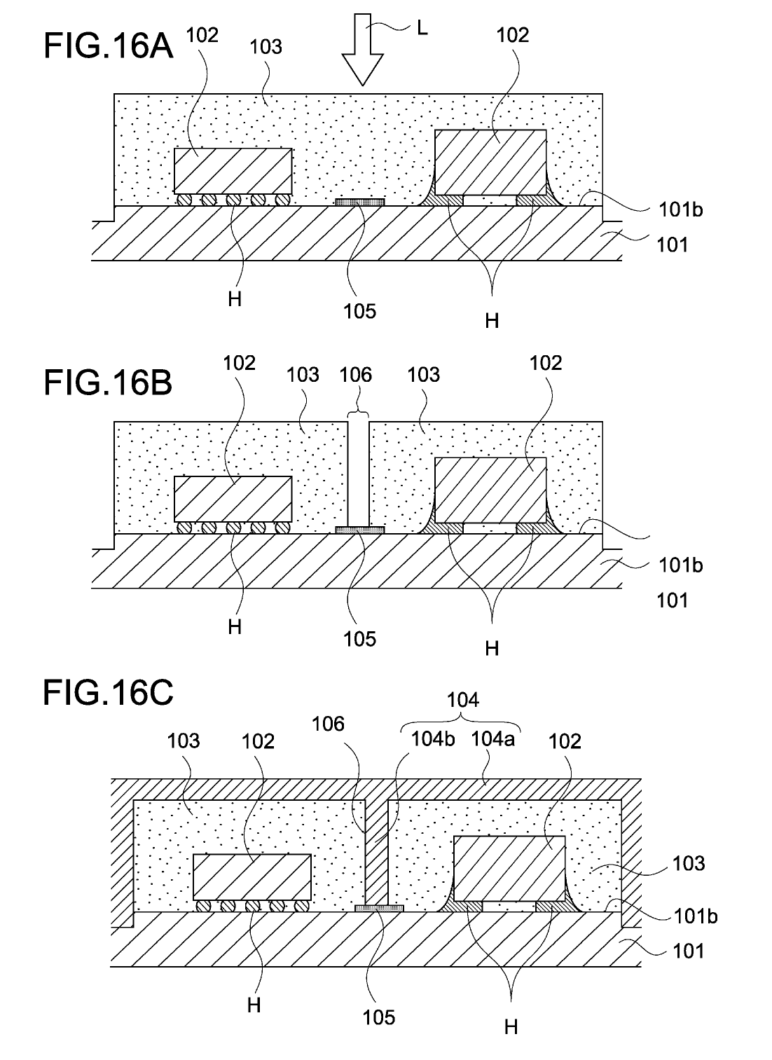

A method of producing the circuit module 101 will be described. FIGS. 15A to 15C and 16A to 16C each is a schematic view showing a method of producing the circuit module 100. The plurality of circuit modules 100 can be produced on one circuit substrate at the same time, and be divided into each circuit module 100. Hereinbelow, one of the circuit modules 100 will be described.

As shown in FIG. 15A, the mount components 102 are mounted on the mount surface 101b of the circuit substrate 101. Mounting can be performed by a variety of mounting methods including solder joint. In this case, the superficial conductor 105 is disposed in advance on the mount surface 101b.

Next, as shown in FIG. 15B, the mount components 102 are filled and covered with a sealing material F on the mount surface 101b. Filling with the sealing material F can be performed by a vacuum printing, for example.

Next, as shown in FIG. 15C, the sealing material F is half-cut per the circuit module 100. For example, the sealing material F can be half-cut by a dicer. Thereafter, the sealing material F is cured to form the sealing body 103. For example, the sealing material F can be cured by baking.

Next, as shown in FIG. 16A, the sealing body 103 is irradiated with laser L and is scanned. Irradiation of the laser L removes linearly the sealing body 103, and the trench 106 shown in FIG. 16B is formed. Depending on a scan path of the laser L, the trench 106 having a shape (a line shape) as shown in FIG. 8 is formed.

Here, when irradiation of the laser L is started, predetermined laser irradiation conditions (the first laser irradiation conditions) are used. After the scan is started, the second laser irradiation conditions having irradiation energy higher than that of the first laser irradiation conditions are used. Before the scan is stopped, the first laser irradiation conditions are used. Then, the irradiation of the laser L is stopped.

The laser irradiation conditions include energy for each shot in pulse laser (average energy), the number of shots per unit area of the sealing body 103, a shot pitch (a space between the shots), etc. The laser irradiation energy is provided to a unit area of the sealing body 103 by the laser irradiation.

In other words, the irradiation energy may be enlarged by increasing the energy of each shot from the first laser irradiation conditions, or by increasing the number of shots per the unit area of the sealing body 103. Alternatively, the irradiation energy may be enlarged by shortening the shot pitch and enlarging overlap regions of the respective shots. Furthermore, the irradiation energy may be enlarged by changing some of the irradiation conditions. In either case, the irradiation conditions where the irradiation energy is enlarged from the first irradiation conditions are defined as the second irradiation conditions.

When the irradiation conditions upon the laser L irradiation start are set to the first laser irradiation conditions, a scan start region of the sealing body 103 is not all removed, and the second trench section 106b is formed as shown in FIG. 9B and FIG. 10.

After the scan is started, the laser L irradiation conditions are set to the second laser irradiation conditions, the sealing body 103 on a scan path is all removed, and the first trench section 106a is formed as shown in FIG. 9A and FIG. 10.

When the irradiation conditions upon the laser L irradiation stop are set to the first laser irradiation conditions, a scan stop region of the sealing body 103 is not all removed, and the second trench section 106b is formed as shown in FIG. 9B and FIG. 10.

The trench 106 is thus formed. When the laser irradiation conditions upon the laser L irradiation start and the scan stop are set to the irradiation conditions so that the irradiation energy becomes small, the trench 106 has the second trench sections 106b disposed at both ends and the first trench section 106a disposed therebetween, as shown in FIG. 8. In this way, the trench 106 is formed in the sealing body 103.

Next, as shown in FIG. 16C, the shield 104 is formed over the sealing bodies 103. The shield 104 can be formed by printing a shielding material or by plating. In this way, the outer shield section 104a is formed over the main surface of the sealing body 103 and the inner shield section 104b is formed within the trench 106 (the first trench section 106a and the second trench section 106b). As the first trench section 106a reaches the superficial conductor 105 as described above, the inner shield section 104b abuts on the superficial conductor 105 within the first trench section 106b.

Next, the shield 104 and the circuit substrate 101 are cut (full-cut) per circuit module 100. For example, the shield 104 and the circuit substrate 101 can be cut by the dicer. In this way, the circuit module 100 shown in FIGS. 13A, 13B and 14 is produced. As described above, as the shield 104 is disposed over the sealing bodies 103 after the trench 106 is formed in the sealing bodies 103, the shape of the trench 106 determines the shape (the depth) of the inner shield section 104b.

### [Advantages]

The circuit module 100 according to the embodiment has the following advantages. In other words, the laser L energy is easily concentrated at the irradiation start position and the irradiation stop position of the laser L. For this reason, if the laser L irradiation energy is constant, the interlayer wirings 101a of the circuit substrate 101 at the irradiation start position and the irradiation stop position may be damaged by the laser L and be broken.

Conversely, if the irradiation energy is constantly decreased during the laser L irradiation, any portion of the trench 106 may not reach the superficial conductor 105, and the inner shield section 104b may not be contacted with the superficial conductor 105. In this case, as the shield 104 is not electrically connected to the superficial conductor 105, the shielding effectiveness may not be provided by the shield 104.

In sharp contrast, by the circuit module 100 according to the embodiment, the laser L irradiation energy is small at the irradiation start position and the irradiation stop position of the laser L, and the second trench section 106b does not reach the superficial conductor 105. Therefore, the interlayer wirings 101a are not damaged when the laser L is started and stopped to be irradiated. Furthermore, the laser L irradiation energy is large at the positions excluding the irradiation start position and the irradiation stop position of the laser L, and the first trench section 106a reaches the superficial conductor 105. In other words, the inner shield section 104b is electrically connected to the superficial conductor 105, thereby sufficiently providing the shielding effectiveness by the shield 104.

### Alternative Embodiment

The trench 106 of the circuit module 100 can have a shape (a line shape) depending on the types or positions of the mount components 102, as described above. Accordingly, the trench 106 may be plural or branched.

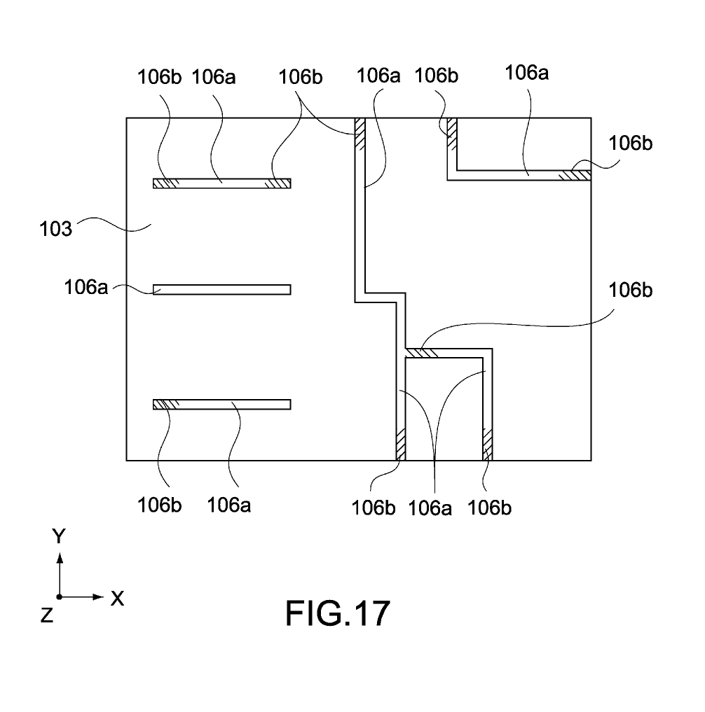

FIG. 17 is a plan view showing other shapes (line shapes) of the trenches 106. As shown in FIG. 17, the second trench sections 106b (shown by hatched lines) can be formed at ends of the trenches 106 formed by a series of the laser scanning, and the first trenches 106a can be formed between the second trench sections 106b. Alternatively, only at either end (either of the irradiation start position or the irradiation stop position) of each trench 106, each second trench section 106b may be formed. Or, at the position where no interlayer wiring 101a is formed in the circuit substrate 101, each trench 106 only having the first trench sections 106a may be formed.

### Second Embodiment

The circuit module according to a second embodiment of the present disclosure will be described.

### [Configuration of Circuit Module]

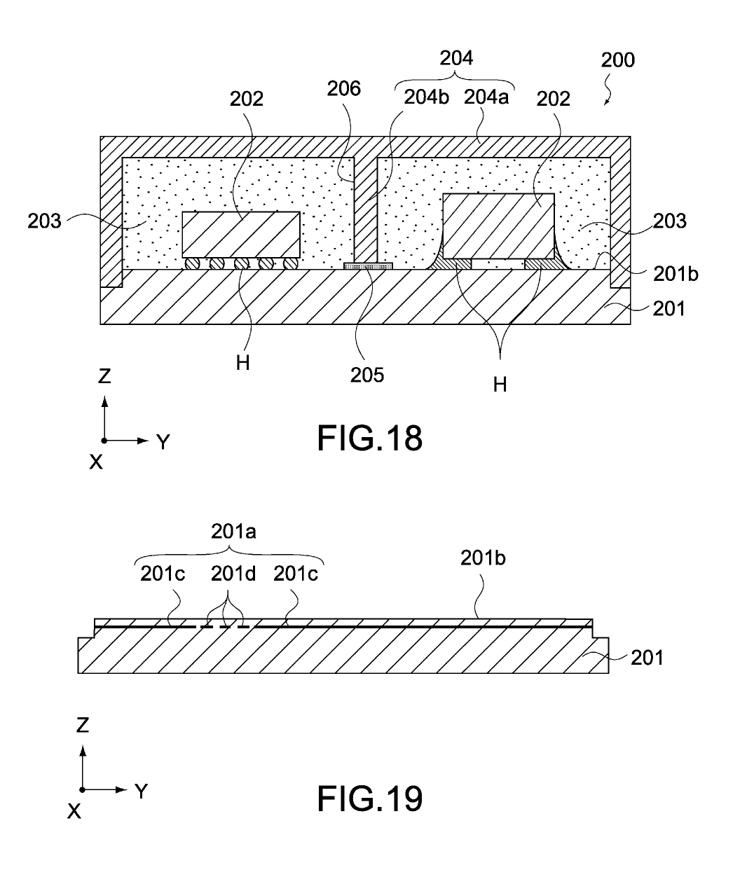

FIG. 18 is a schematic view of a circuit module 200 according to the second embodiment of the present disclosure. As shown in FIG. 18, the circuit module 200 includes a circuit substrate 201, mount components 202, sealing bodies 203, and a shield 204. Although a size or a shape of the circuit module 200 is not especially limited, the circuit module 200 may be a rectangular parallelepiped having a size of tens mm squares and a thickness of several mms.

On the circuit substrate 201, mount components 202 are mounted. The circuit substrate 201 can be a multi-layer substrate on which a plurality of layers made of an insulating material such as a glass epoxy-based material and an insulating ceramic material is laminated. Within the layers, interlayer wirings 201a can be formed.

FIG. 19 is a sectional view of a circuit substrate 201 showing the interlayer wirings 201a. As shown in FIG. 19, the interlayer wirings 201a include ground wirings 201c and a non-ground wiring 201d. The ground wirings 201c are electrically connected to a ground of the circuit module 200, and the non-ground wiring 201d is not electrically connected to the ground wirings 201c. The non-ground wiring 201d is, for example, a signal line between mount components 202.

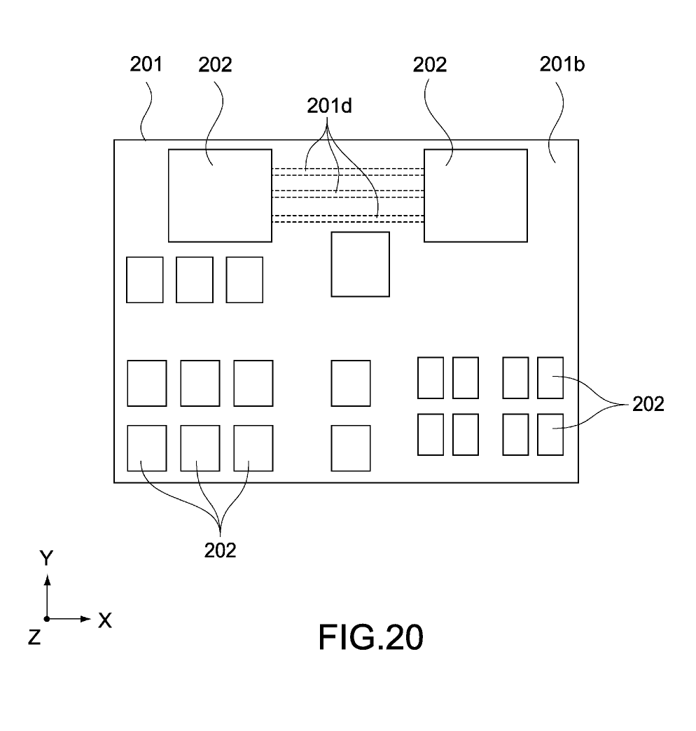

FIG. 20 is a plan view of the circuit substrate 201 and the mount components 202 showing the non-ground wiring 201d. As shown in FIG. 20, the non-ground wiring 201d can be configured to connect the mount components 202. The non-ground wiring 201d is not limited to the signal line of the mount components 202, and is not limited to the position that the mount components 202 are connected. Hereinafter, a surface on which the mount components 202 are mounted is defined as a mount surface 201b.

On the mount surface 201b, a superficial conductor 205 is formed, as shown in FIG. 18. The superficial conductor 205 is made of a conductive material, or may be a conductive paste applied and cured on the mount surface 201b or a metal film formed by plating etc. on the mount surface 201b. The superficial conductor 205 can be disposed on the mount surface 201b along a trench 206 as described later.

The superficial conductor 205 is connected to the ground wiring 201c, and can be electrically connected to the ground terminal of the circuit module 200 via the ground wiring 201c, and therefore can have the same potential as a ground potential of the circuit module 200.

The mount component 202 mounted on the mount surface 201b of the circuit substrate 201 is an integrated circuit (IC), a capacitor, an inductor, a resistor, a crystal oscillator, a duplexer, a filter, a power amplifier, or the like, for example. The mount component 202 can be mounted on the mount surface 201b by solder joint using solder H. The number or placement of mount components 202 is not especially limited.

The sealing bodies 203 are made of a sealing material, and cover the mount components 202 on the mount surface 201b. For example, the sealing material is an insulating resin such as an epoxy resin to which silica or alumina is added. After the mount components 203 are mounted on the mount surface 201b, peripherals of the mount components 202 are filled with a fluid sealing material and the sealing material is cured to provide the sealing bodies 203. The trench 206 is formed in the sealing bodies 203, which is described later.

The shield 204 is made of a shielding material that is a conductive material, and functions as a shield against electromagnetic interruption. For example, the shielding material may be a conductive resin such as an epoxy resin containing conductive particles such as Ag and Cu, or may be a metal film formed on the sealing body 203 by plating etc.

The shield 204 has an outer shield section 204a covering the main surface of the sealing body 203 and an inner shield section 204b formed within the trench 206. The inner shield section 204b abuts on the superficial conductor 205 via the trench 206, and is electrically connected to the superficial conductor 205. Details about the inner shield section 204b will be described later.

The outer shield section 204b is successive with the inner shield section 204a, and is electrically connected to the superficial conductor 205 via the inner shield section 204b. As described above, the superficial conductor 205 can be a ground of the circuit module 200, and the shield 204 can be a ground potential.

The circuit module 200 has an overall configuration as described above. In the circuit module 200, the electromagnetic interruption can be prevented by the shield 204. Specifically, the electromagnetic interruption from outside of the circuit module 200 to the mount components 202 or the electromagnetic interruption from the mount components 202 to outside of the circuit module 200 is prevented by the outer shield section 204a. Also, the electromagnetic interruption between the mount components 202 is prevented by the inner shield section 204b.

### [About Trench and Inner Shield Section]

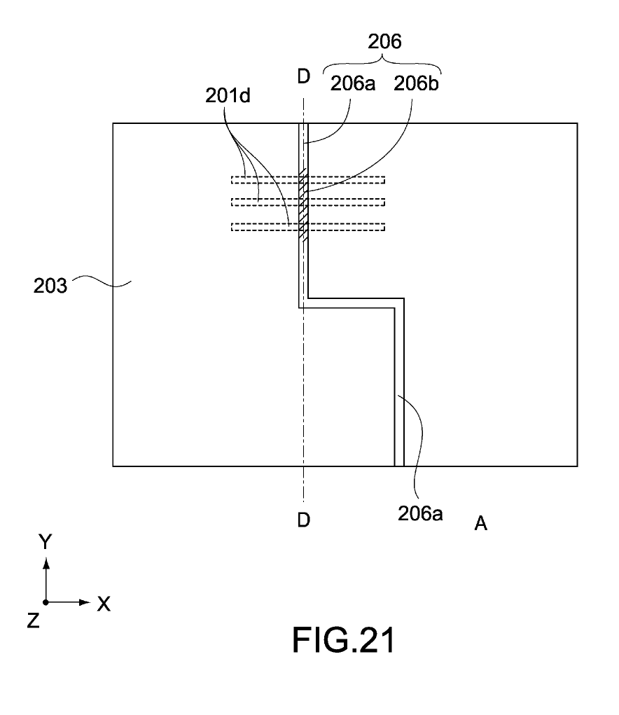

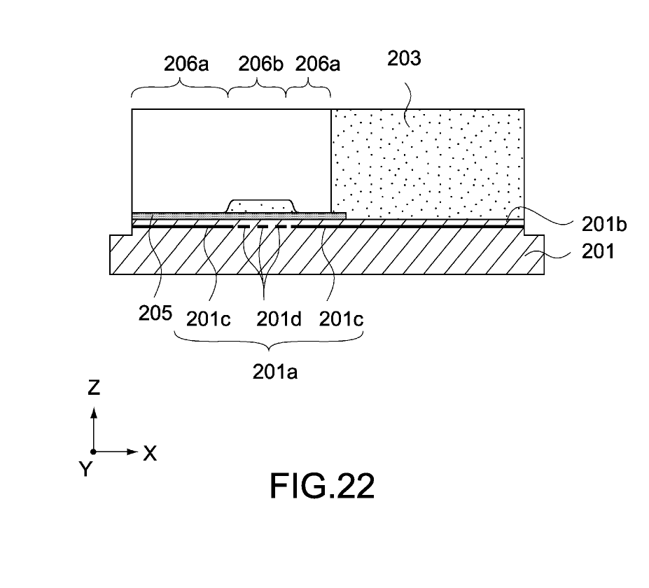

Trench 206 has different depths (in the Z direction). FIG. 21 is a plan view of the sealing body 203 showing the trench 206. As shown in FIG. 21, the trench 206 has first trench sections 206a and a second trench section 206b. The second trench section 206b is shown by hatched lines in FIG. 21. FIG. 22 is a sectional view of the sealing body 203 showing the trench 206 along the D-D line shown in FIG. 21.

The first trench section 206a has a depth reaching the superficial conductor 205 as shown in FIG. 22 (also see FIG. 9A). On the other hand, the second trench section 206b does not reach the superficial conductor 205 as shown in FIG. 22 (also see FIG. 9B).

As shown in FIG. 22, the second trench section 206b is formed at the area where the non-ground wiring 201d is disposed in a lower side of the sealing body 203. On the other hand, the first trench sections 206a are formed at the area where the non-ground wiring 201d is not disposed in a lower side of the sealing body 203.

Similar to the first embodiment, the trench 206 can be formed by irradiating and scanning the sealing bodies 203 with laser. By adjusting the laser irradiation conditions on that occasion, the first trench sections 206a and the second trench section 206b can be formed. In other words, the first trench sections 206a are formed by irradiating the sealing bodies 203 with the laser having sufficiently high irradiation energy, and the second trench section 206b is formed by irradiating the sealing bodies 203 with the laser having sufficiently low irradiation energy.

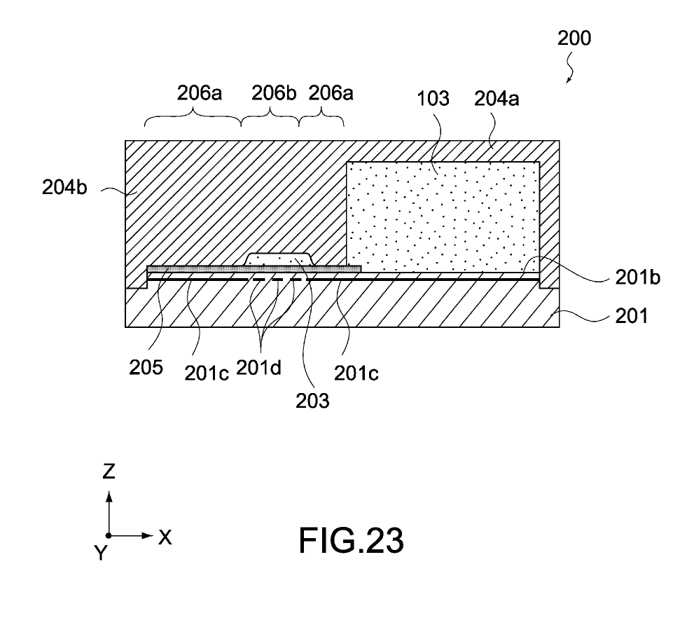

The inner shield section 204b is formed within the trench 206. FIG. 23 is a sectional view of the circuit module 200 showing the inner shield section 204b. As shown in FIG. 23, the inner shield section 204b abuts on the superficial conductor 205 via the first trench sections 206a (also see FIG. 13A), and is electrically connected to the superficial conductor 205. In other words, as shown in FIG. 23, the inner shield section 204b is assuredly electrically connected to the superficial conductor 205, even though a portion of the inner shield section 204b (a portion formed within the second trench section 206b) does not abut directly on the superficial conductor 205.

### [Advantages]

The circuit module 200 according to the embodiment has the following advantages. In other words, the laser irradiated to the sealing bodies 203 in order to form the second trench section 206b does not reach superficial conductor 205, as descried above. Thus, the laser is prevented from passing through the superficial conductor 205 to reach the non-ground wiring 201d, and the non-ground wiring 201d is prevented from damaging. Meanwhile, the laser irradiated to the sealing bodies 203 in order to form the first trench sections 206a reaches the superficial conductor 205, the inner shield section 204b is electrically connected to the superficial conductor 205 via the first trench sections 206a, and the shielding effectiveness of the shield 204 will be effectively provided.

When the laser reaches the non-ground wiring 201d, the trench 206 formed thereby will reach the non-ground wiring 201d and the inner shield section 204b formed within the trench 206 may be short-circuited with the non-ground wiring 201d. However, in the area where the non-ground wiring 201d is disposed (the area where the first trench sections 206a are formed), there is no problem if the laser passes through the superficial conductor 205 and reaches the ground wiring 201c. This is because the inner shield section 204b is scheduled to electrically connect to the ground wiring 201c.

As described above, the circuit module 200 according to the embodiment can prevent the non-ground wiring 201d from damaging and sufficiently provides the shielding effectiveness by the shield 204.

### Alternative Embodiment

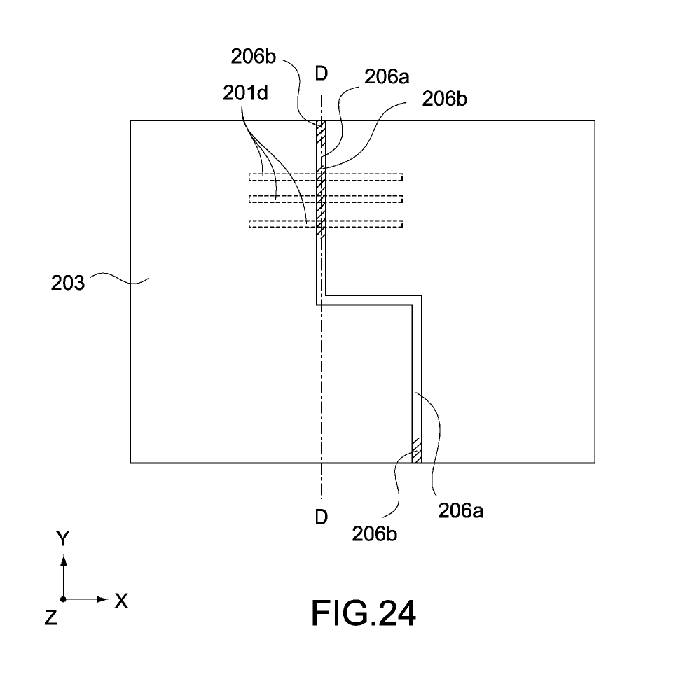

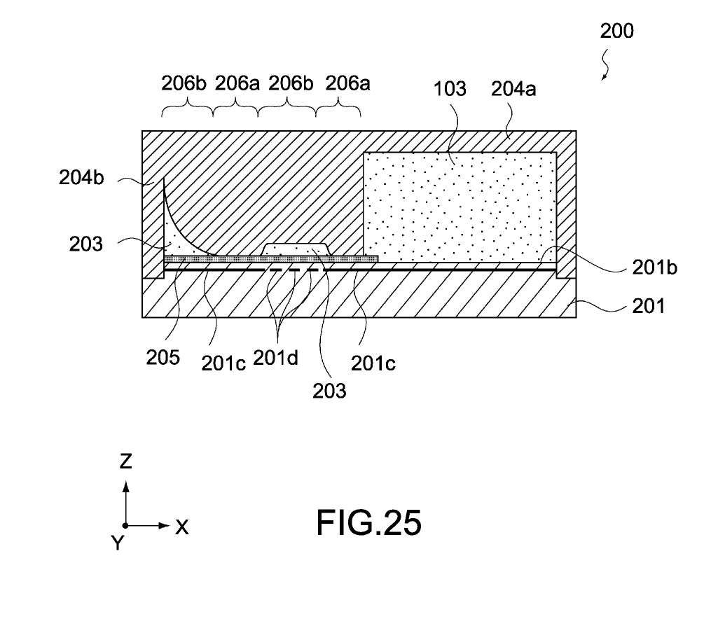

FIG. 24 is a plan view of the sealing bodies 203 of the circuit module 200 according to an alternative embodiment. FIG. 25 is a sectional view of the circuit module 200. As shown in FIGS. 24 and 25, the second trench sections 206b may be formed on the ends of the trench 206 similar to the first embodiment, as well as on the non-ground wiring 201d. In this way, damaging the non-ground wiring 201d and the interlayer wirings 201a at the laser irradiation start point and the stop point by the laser irradiation can be avoided.

While the embodiments of the present disclosure are described, it should be appreciated that the disclosure is not limited to the above-described embodiments, and variations and modifications may be made without departing from the spirit and scope of the present disclosure.

1. A circuit module, comprising:
a circuit substrate being a multi-layer substrate on which interlayer wirings are formed and including a mount surface on which a superficial conductor is disposed;
a mount component mounted on the mount surface;
a sealing body formed on the mount surface, the sealing body covering the mount component and having a trench including a first trench section reaching the superficial conductor and a second trench section not reaching the superficial conductor which is formed from a main surface of the sealing body to the mount surface; and
a shield having an outer shield section that covers the sealing body and an inner shield section formed within the trench,
wherein the interlayer wirings include a ground wiring electrically connected to a ground of the circuit module and a non-ground wiring not electrically connected to the ground wiring,
the second trench section is formed at the area where the non-ground wiring is disposed in a lower side of the sealing body, and
the first trench section is formed at the area where the non-ground wiring is not disposed in a lower side of the sealing body.

2. The circuit module according to claim 1, wherein
the second trench section is formed at an end of the trench, and
the first trench section is formed between the second trenches.

3. (canceled)

4. The circuit module according to claim 1, wherein
the mount component includes a plurality of mount components, and
the trench is formed between the plurality of mount components such that the mount components are separated.

5. A method of producing a circuit module, comprising:
preparing a circuit substrate being a multi-layer substrate on which interlayer wirings are formed and including a mount surface on which a superficial conductor is disposed,
mounting at least one mount component on the mount surface,
forming a sealing body on the mount surface that covers the mount component,
forming a trench including a first trench section reaching the superficial conductor and a second trench section not reaching the superficial conductor on the sealing body from a main surface of the sealing body to the mount surface, and
forming a shield having an outer shield section that covers the sealing body and an inner shield section formed within the trench.

6. The method of producing a circuit module according to claim 5, wherein
in forming the trench, the second trench section is formed by starting the laser irradiation under first laser irradiation conditions, the first trench section is formed by scanning the laser under second laser irradiation conditions having irradiation energy higher than that of the first laser irradiation conditions, and the second trench section is formed by stopping the laser irradiation under the first laser irradiation conditions.

7. The method of producing a circuit module according to claim 5, wherein
in forming the trench, the second trench section is formed by irradiating an area where the non-ground wiring is disposed in an upper side of the sealing body with laser under the first laser irradiation conditions, and the first trench section is formed by irradiating area where the non-ground wiring is not disposed in an upper side of the sealing body with laser under the second laser irradiation conditions having irradiation energy higher than that of the first laser irradiation conditions.
